(19) United States
(12) Patent Application Publication
(10) Pub. No.: US 2011/0198481 A1
(43) Pub. Date: Aug. 18, 2011

(54) Image sensor and operating method

(75) Inventors: Seong Jin Kim, Hwaseong-si (KR); Sang Woo Han, Seoul (KR)

(73) Assignee: SAMSUNG ELECTRONICS Co., LTD., Suwon-si (KR)

(21) Appl. No.: 12/929,681

(22) Filed: Feb. 8, 2011

(30) Foreign Application Priority Data
Feb. 12, 2010 (KR) 10-2010-0013111

(51) Int. Cl. H01L 27/148

(52) U.S. Cl. 250/208.1; 257/222; 257/E27.151

(57) ABSTRACT

An image sensor and a method of operating the image sensor are provided. At least one pixel of the image sensor includes a detection portion including a plurality of doping areas having different pinning voltages, and a demodulation portion to receive an electron from the detection portion, and to demodulate the received electron.

### CROSS-REFERENCE TO RELATED APPLICATIONS

This application claims the priority benefit of Korean Patent Application No. 10-2010-0013111, filed on Feb. 12, 2010, in the Korean Intellectual Property Office, the disclosure of which is incorporated herein by reference.

### BACKGROUND

1. Field

One or more embodiments relate to an image sensor, a structure of a pixel of the image sensor, and a method of operating the same.

2. Description of the Related Art

Currently, portable devices having image sensors, such as digital cameras, mobile communication terminals, and the like, are being developed and marketed. These image sensors are made up by an array of small photodiodes referred to as pixels or photosites. In general, a pixel does not directly extract a color from light, but converts a photon of a wide spectrum band into an electron. Accordingly, the pixel of the image sensor may need to receive only light within a band necessary for obtaining a color from the light of the wide spectrum band. Each pixel of the image sensor can convert a photon corresponding to a specific color into an electron by combining a color filter and the like.

To obtain a three-dimensional (3D) image using an image sensor, color and also information about the distance between an object and the image sensor need to be obtained. In general, a reconstituted image with respect to the distance between the object and an image sensor is expressed as a depth image in the related field. The depth image may be obtained using infrared light outside a region of visible light, though other wavelengths are available.

A method of acquiring information regarding a distance from a sensor to an object may be broadly divided into an active scheme and a passive scheme. The active scheme may typically include a triangulation scheme of calculating a distance using a Time-of-Flight (TOF) used to measure a travel time of light radiated to an object and reflected and returned from the object, and using a triangulation of detecting a location of a light radiated and reflected by a laser spaced by a predetermined distance from a sensor. The passive scheme may typically include a scheme of calculating a distance to an object based on only image information, not radiating a light, and may be employed in a stereo camera.

A TOF-based depth capturing technology may detect a change in phase when a radiated light having a modulated pulse is reflected and returned from an object. Here, the change in phase may be computed based on an amount of electric charges. The radiated light may be an invisible Infrared Ray (IR) that is harmless to a human body. Additionally, to detect a time difference between a radiated light and a reflected light, a depth pixel array that differs from a general color sensor may be used.

### SUMMARY

According to one or more embodiments, there is provided an image sensor, with at least one pixel of the image sensor including a detection portion to transfer an electron, generated by the detection portion after receiving light, with the detection portion including a plurality of doping areas having different pinning voltages to apply an e-field in the detection portion to transfer the electron toward a demodulation portion of the pixel, and the demodulation portion to transfer the electron toward at least one node to accumulate one or more electrons.

The pixel may be configured to apply another e-field that causes the electron to be transferred by the demodulation portion toward the at least one node to accumulate one or more electrons.

In addition, the plurality of doping areas may respectively include a plurality of p-layers, and wherein, as each of the plurality of n-layers is configured to be increasingly closer to the demodulation part, a respective pinning voltage of each of the plurality of n-layers becomes higher. The respective pinning voltage of each of the plurality of n-layers may be based further on a respective doping density.

The plurality of doping areas may respectively include a plurality of p-layers, and wherein, as each of the plurality of p-layers is configured to be increasingly closer to the demodulation portion, a respective pinning voltage of each of the plurality of p-layers becomes higher. The respective pinning voltage of each of the plurality of p-layers may be further based on a respective doping density.

The detection portion may be configured with a pinned photodiode including the plurality of doping areas.

The image sensor may further include a photogate receive the electron transferred by the detection portion toward the demodulation portion. The photogate may be included in the demodulation portion. In addition, the photogate may be shielded from receipt of the light.

The pixel may be configured such that a changing of electric potential of the photogate controls an application of another e-field of the demodulation portion that causes the received electron to be transferred from the photogate toward the at least one node to accumulate one or more electrons.

The pixel may be further configured such that an electric potential of the photogate is lower than an electric potential of the detection portion and an electric potential of a first transfer node in a first time period, and the electric potential of the photogate is higher than the electric potential of the detection portion and the electric potential of the first transfer node in a second time period, immediately after the first time period.

Here, the pixel may be further configured such that an electric potential of the photogate is lower than an electric potential of the detection portion and an electric potential of a second transfer node in a third time period, immediately after the second time period, such that the electric potential of the photogate and the first transfer node in the third time period do not cause an electron stored by the photogate to be transferred to the first transfer node and such that the electric potential of the photogate and the second transfer node in the third time period cause the electron stored by the photogate to be transferred to the second transfer node.

The pixel may be further configured such that the electric potential of the photogate and the electric potential of the detection portion in the second time period causes the electron to be transferred from the detection portion to the photogate, while the electric potential of the photogate and the electric potential of the first transfer node causes the electron to not be transferred to the first transfer node.

The pixel may be further configured such that the electric potential of the photogate and the electric potential of the detection portion in the first time period causes the electron to be transferred within the detection portion toward an edge of the detection portion close to the photogate and to not be stored by the photogate, and the electric potential of the photogate and the electric potential of the first transfer node in the first time period causes an electron stored by the photogate to be transferred to the first transfer node.

The pixel may be further configured such that when the electric potential of the photogate is greater than the first transfer node and a second transfer node in the second time period, with the second transfer node being configured to be transferred an electron from the photogate, the photogate stores a received electron and does not transfer the stored electron to either of the first transfer node and the second transfer node in the second time period.

The pixel may be further configured such that an electron stored in the photogate before the first time period is moved to the first transfer node in the first time period, and the electron transferred by the detection portion toward the demodulation portion is moved to the photogate in the second time period.

According to one or more embodiments, there is provided an image sensor, with at least one pixel including a demodulation portion to demodulate a stored electron through at least one transfer node, the stored electron being stored by the demodulation portion prior to a first time period, and a detection portion to transfer a generated electron to a front side of the demodulation portion in the first time period, the generated electron being generated by the detection portion upon receiving light in the first time period, wherein the pixel is configured to move the transferred electron to the demodulation portion in a second time period.

The pixel may be configured such that a potential of the detection portion applies a drift force to transfer the generated electron to at least the front side of the demodulation unit in the first time period, at least a potential of the detection portion in the second time period applies a drift force for the moving of the transferred electron to a storage of the demodulation portion, and at least one potential of the demodulation portion in the second time period prevents application of a drift force to transfer the stored electron to the at least one transfer node within the demodulation portion during the second time period.

The pixel may be configured to move the stored electron to the at least one transfer node during the first time period.

The detection portion may include a plurality of doping areas, and a pinning voltage of each of the plurality of doping areas is based on a respective doping density or junction depth. The detection portion may further be configured with a pinned photodiode including the plurality of doping areas. The pinned photodiode may have a narrowing geometry toward the demodulation portion. The pinned photodiode may have a widening geometry toward the demodulation portion. Further, the demodulation portion may include a photogate.

According to one or more embodiments, there is provided a method of operating an image sensor that includes at least one pixel including a detection portion to generate an electron upon receipt of light, and a demodulation portion to demodulate the generated electron including a first transfer node and a second transfer node, the method including controlling an electric potential of the detection portion to transfer the generated electron toward the demodulation portion, controlling an electric potential within the pixel to cause the generated electron to be stored for a predetermined time period, and controlling an electric potential of the demodulation portion to cause the stored electron to be transferred after the predetermined time period to the first transfer node.

The method may further include controlling an electric potential within the pixel to cause another generated electron to be stored for the predetermined time period, and controlling at least one electric potential of the demodulation portion to cause the other stored electron to be transferred after the predetermined time period to the second transfer node, and to cause the other stored electron to not be transferred after the predetermined time period to the first transfer node.

The method may further include accumulating first electrons transferred to the first transfer node and accumulating second electrons transferred to the second transfer node, and comparing the accumulated first electrons to the accumulated second electrons and determining a time of flight for the light.

According to one or more embodiments, there is provided at least one non-transitory medium including computer readable code to control at least one processing device to implement one or more methods disclosed herein.

According to one or more embodiments, there is provided a method of operating an image sensor that includes at least one pixel including a detection portion to generate an electron upon receipt of light, and a demodulation portion to demodulate the generated electron, the demodulation portion including a photogate, a first transfer node, and a second transfer node, the method including storing the electron generated by the detection portion in the photogate in a first time period, and demodulating the electron stored in the photogate, through one of the first transfer node and the second transfer node, in a second time period, immediately after the first time period.

The storing, in the first period, may include setting an electric potential of the photogate and electric potentials of both of the first transfer node and the second transfer node, such that the electric potential of the photogate is higher than the electric potentials of both the first transfer node and the second transfer node.

The demodulating, in the second period, may include setting an electric potential of the photogate and an electric potential of one of the first transfer node and the second transfer node, such that the electric potential of the one of the first transfer node and the second transfer node is higher than an electric potential of the photogate.

The method may further include controlling an electric potential of the photogate to be lower than an electric potential of the detection portion and an electric potential of the second transfer node, while controlling the electric potential of the first transfer node such that the electric potential of the photogate and the first transfer node do not cause the stored electron to be transferred to the first transfer node and controlling the electric potential of the photogate and the second transfer node to cause the stored electron stored to be transferred to the second transfer node.

The method may further include controlling an electric potential of the photogate and an electric potential of the detection portion to cause the electron generated by the detection portion to be transferred from the detection portion to the photogate, while controlling electric potentials of the first transfer node and the second transfer node to cause the stored electron to not be transferred to either of the first transfer node and the second transfer node.

The method may further include controlling an electric potential of the photogate and an electric potential of the detection portion to cause the electron generated by the detection portion to be transferred within the detection portion toward an edge of the detection portion close to the photogate and to not be moved to the photogate, while controlling the electric potential of the photogate and the electric potential of the first transfer node to cause the stored electron to be transferred to the first transfer node.

The method may further include controlling an electric potential of the photogate to be greater than electrical potentials of both the first transfer node and the second transfer node, to prevent transfer of the stored electron of the photogate to either of the first transfer node and the second transfer node.

Additional aspects of embodiments will be set forth in part in the description which follows and, in part, will be apparent from the description, or may be learned by practice of the disclosure.

### BRIEF DESCRIPTION OF THE DRAWINGS

These and/or other aspects will become apparent and more readily appreciated from the following description of embodiments, taken in conjunction with the accompanying drawings of which:

FIG. 1 illustrate a structure of a pixel of a conventional image sensor;

FIGS. 2 and 3 illustrate timing diagrams to explain an effect of demodulation speed on measuring of a depth;

FIG. 4 illustrates a diagram of an image sensor, according to one or more embodiments;

FIG. 5 illustrates a plane diagram of a pixel of an image sensor, according to one or more embodiments;

FIG. 6 illustrates a cross-sectional diagram taken along line A-A′ of FIG. 5, according to one or more embodiments;

FIG. 7 illustrates a diagram of differing junction depths of a detection part, such as that of FIG. 6, according to one or more embodiments;

FIG. 8 illustrates a cross-sectional diagram taken along line B-B′ of FIG. 5, according to one or more embodiments;

FIG. 9 illustrates a diagram of an electric potential formed on a detection part, such as shown in FIG. 5, according to one or more embodiments;

FIG. 10 illustrates a diagram of an electric potential formed on a demodulation part, such as shown in FIG. 5, according to one or more embodiments;

FIGS. 11 and 12 illustrate diagrams a method of operating an image sensor, according to one or more embodiments;

FIG. 13 illustrates a timing diagram of the operations of the pixel shown in FIGS. 11 and 12, according to one or more embodiments;

FIGS. 14 and 15 illustrate diagrams of an electric potential of a pixel of an image sensor, according to one or more embodiments;

FIGS. 16 through 19 illustrate diagrams of various modifications of a pixel of an image sensor, according to one or more embodiments.

### DETAILED DESCRIPTION

Reference will now be made in detail to one or more embodiments, illustrated in the accompanying drawings, wherein like reference numerals refer to like elements throughout. In this regard, embodiments of the present invention may be embodied in many different forms and should not be construed as being limited to embodiments set forth herein. Accordingly, embodiments are merely described below, by referring to the figures, to explain aspects of the present invention.

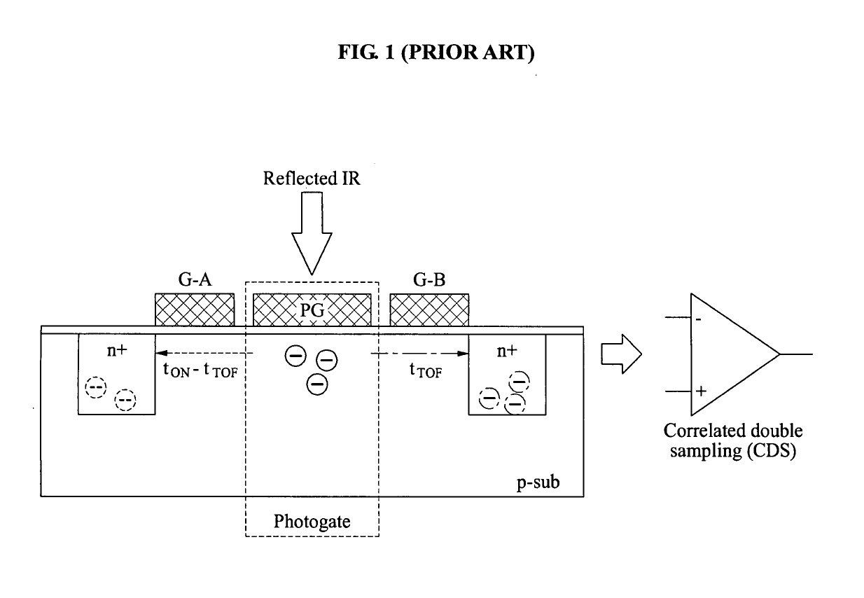

In FIG. 1, a photogate element is used to detect and demodulate reflected light. When a voltage is applied to a photo gate (PG), a depletion area may be formed below the PG. In this situation, when the reflected IR is incident to the PG, an electron may be generated below the PG. The electron generated for demodulation is directly transferred to first and second accumulation nodes respectively through operation of gates G-A or G-B. However, since the light is reflected from an object in a very short time, for example several tens nanoseconds (ns), a large number of electrons may not be generated. After an electron is periodically generated, the electron may be accumulated in the first accumulation node shown near gate G-A and accumulated in the second accumulation node shown near gate G-B. Finally, after a predetermined period of time, a TOF may be obtained by reading the electron from each accumulation node, and thus distance information may be acquired. As shown in FIG. 1, an electron proportional to t_{ON}-t_{TOF} may be accumulated in the first accumulation node, and an electron proportional to t_{TOF} may be accumulated in the second accumulation node, and accordingly, the distance may be obtained. Though distances may be theoretically obtained through this pixel structure and operation, due to the speed of light, light reflected from an object located within 10 m would be returned within several tens of nanoseconds.

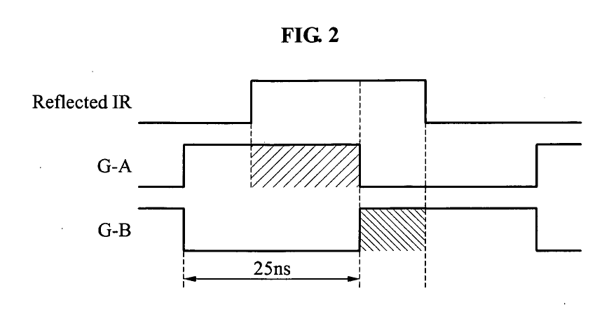

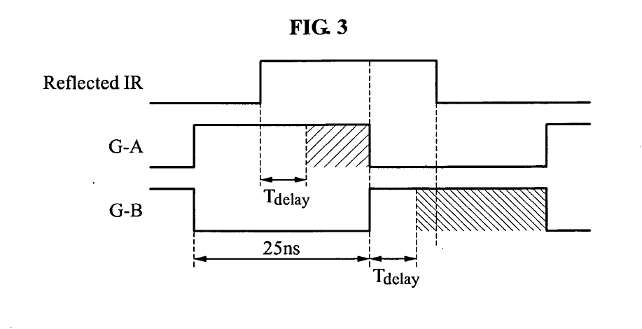

FIGS. 2 and 3 illustrate effects of the demodulation speed on depth measurement. Dashed lines shown in respective G-A and G-B waveforms indicate an amount of electric charges generated, with the waveform change in both G-A and G-B waveforms initially occurring at or near the same time as the light is emitted. For example, when a modulation frequency is 20 MHz, the electron may be transferred by applying a voltage to each transfer gate for 25 ns. As shown in FIG. 2, when the transfer time is short (e.g., less than 1 ns), an amount of electric charges in an accumulation node may be proportional to the TOF, and thus it is possible to accurately measure a depth. Conversely, as shown in FIG. 3, when the electron transfer takes a long time, the amount of electric charges may not be proportional to the TOF, and as a result, an error corresponding to T_{delay} may occur, which may result in errors when measuring a depth. FIG. 2 is an example of a high-demodulation speed, while FIG. 3 is an example of a low-demodulation speed.

There are two reasons that an electron is transferred, for example, drift and diffusion processes. To explain briefly, the drift process enables the electron to be moved by an electric field (e-field), and the diffusion process enables the electron to be moved by diffusion. Generally, the drift process is faster than at least ten times the diffusion process.

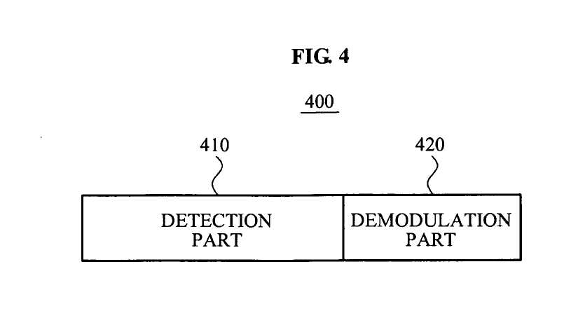

In view of the above, FIG. 4 illustrates an image sensor 400, according to one or more embodiments.

Referring to FIG. 4, at least one pixel of the image sensor 400 may include a detection part 410 and a demodulation part 420, for example.

The detection part 410 may receive a light photon, generate an electron based on the received light photon, and transfer the generated electron to the demodulation part 420. Here, the detection part 410 may include a plurality of doping areas, and may transfer the electron to demodulation part 420 based on a difference in pinning voltage between the plurality of doping areas. The detection part 410 may be configured with a pinned photodiode including the plurality of doping areas. Here, in one or more embodiments, the pinned photodiode may have a structure of P+/N/P-sub. The pinned photodiode may maintain a pinning voltage and decrease a dark current when operated.

The demodulation part 420 may demodulate the electron transferred from the detection part 410, through at least one transfer node. The demodulation part 420 may include at least one of an accumulation node and a Floating Diffusion (FD) node. Here, a demodulation performed by the demodulation part 420 refers to transferring of the electron received from the detection part 410 to the accumulation node or the FD node through the at least one transfer node. The demodulation part 420 may be configured with a photogate.

A method of operating at least one pixel of the image sensor 400 may include a scheme of applying an electric field (e-field) to the detection part 410 so that an electron may be moved to the demodulation part 420. In other words, the detection part 410 may receive a light photon, generate an electron, and transfer the electron to a front side of the demodulation part 420 in a first time period. The demodulation part 420 may demodulate an electron stored prior to the first time period, using at least one transfer node. Here, the electron transferred to the front side of the demodulation part 420 may be moved to the demodulation part 420 in a second time period. Here, with respect to an electron, the movement or transfer of an electron will be considered equivalent to the electron being caused to drift to/from the identified locations,

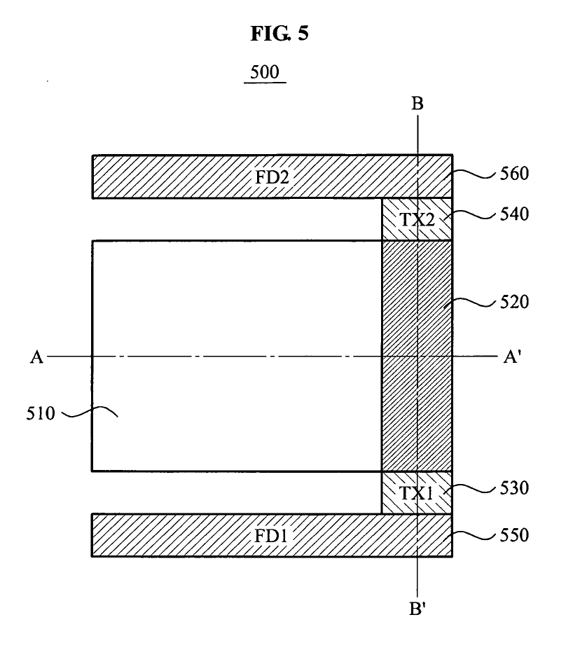

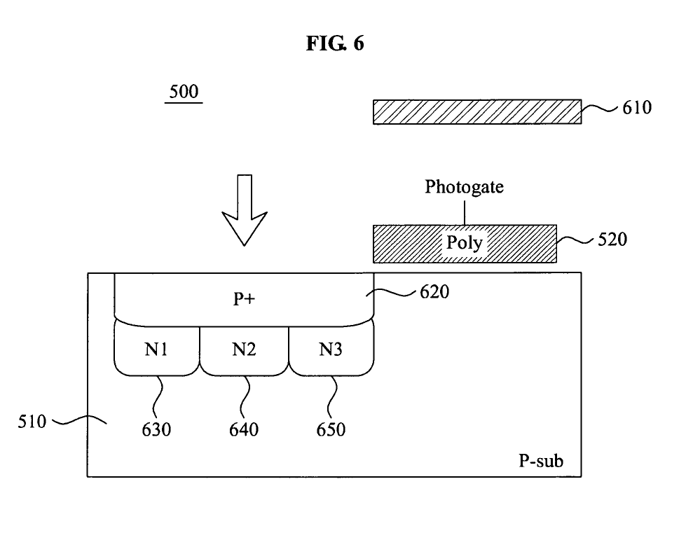

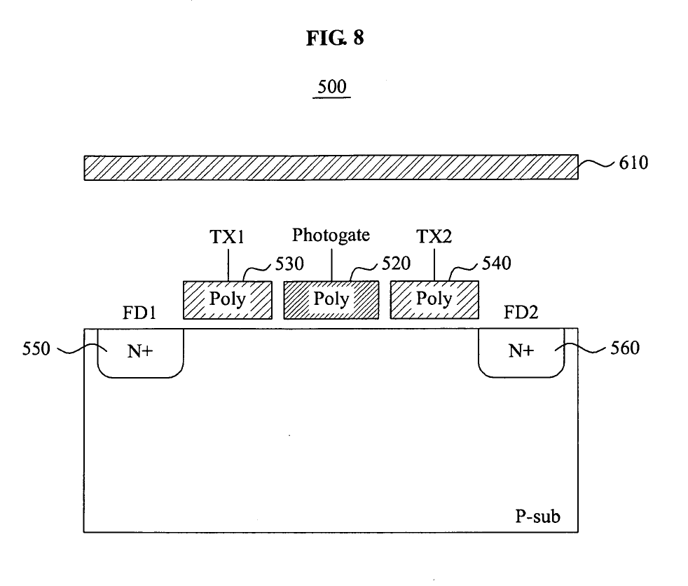

FIG. 5 illustrates a plane diagram of a pixel 500 of an image sensor, according to one or more embodiments. FIG. 6 illustrates a cross-sectional diagram taken along line A-A′ of FIG. 5, and FIG. 8 illustrates a cross-sectional diagram taken along line B-B′ of FIG. 5, according to one or more embodiments.

The pixel 500 of the image sensor may include a detection part 510, a photogate 520, a first transfer node TX1 530, a second transfer node TX2 540, a first FD node FD1 550, and a second FD node FD2 560. Here, the photogate 520, the first transfer node TX1 530, the second transfer node TX2 540, the first FD node FD1 550, and the second FD node FD2 560 may collectively be considered a demodulation part, corresponding to the demodulation part 420 of FIG. 4.

The detection part 510 of FIG. 5 may correspond to the detection part 410 of FIG. 4. Accordingly, the detection part 510 may receive a light photon, generate an electron, and transfer the generated electron to the demodulation part. Additionally, the detection part 510 may be configured with a pinned photodiode. Here, the detection part 510 may include a plurality of doping areas 620, 630, 640, and 650 to transfer electrons. The plurality of doping areas 620, 630, 640, and 650 may include a P+ layer 620, and n-layers 630, 640, and 650 that are placed below the P+ layer 620. As each of the n-layers 630, 640, and 650 is configured to be closer to the demodulation part, the respective pinning voltage of each of the n-layers 630, 640, and 650 may be higher. Additionally, a pinning voltage of each of the n-layers 630, 640, and 650 may be configured based on a doping density or a junction depth of each of the respective n-layers 630, 640, and 650. For example, the doping density may be increased in an order of the n-layers N1 630, N2 630, and N3 630. Specifically, a pinning voltage of the n-layer N1 630 may be lower than a pinning voltage of the n-layer N2 640, and a pinning voltage of the n-layer N3 650 may have a highest pinning voltage among the n-layers 630, 640, and 650. When the n-layers 630, 640, and 650 are configured to have higher pinning voltages as they become closer to the demodulation part, the electron generated by the detection part 510 may be moved to the demodulation part by an e-field generated by the increasing pinning voltages.

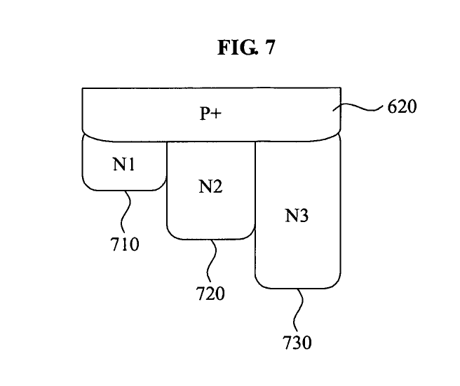

FIG. 7 illustrates junction depths of a detection part 510, such as that of FIG. 6, which are configured with different increasing junction depths. In FIG. 7, a junction depth of an n-layer N3 730 is deeper than a junction depth of an n-layer N1 710 and a junction depth of an n-layer N2 720, and the junction depth of the n-layer N2 720 is deeper than the junction depth of the n-layer. N1 710. Here, the n-layer N3 730 may be disposed in a closest location to the demodulation part.

Referring to FIG. 6, according to a same principle as described above, the P+ layer 620 may be divided into a plurality of areas, and a pinning voltage of each of the plurality of areas may be based on the doping density or junction depth of each of the plurality of areas. Here, the n-layers 630, 640, and 650 may be replaced with a single n-layer. Additionally, a plurality of P doping areas may be formed on an N-substrate (N-sub), and an N+ doping area may be formed on the plurality of P doping areas, so that a pixel of an image sensor may be implemented, for example. In other words, depending on embodiment, the P-sub 510, the p-layers 630, 640, and 650, and the P+ layer 620 may be respectively replaced with an N-sub, p-layers, and an N+ layer. In such an embodiment, the detection part 510 may have a structure of N+/P/N-sub. When the detection part 510 has the structure of N+/P/N-sub, the N+ layer may be divided into a plurality of areas, and a doping density or a junction depth of each of the plurality of areas selectively configured, and the p-layers may be replaced with a single p-layer.

There is no limitation to the above-described embodiment, and accordingly, it will be interpreted that the detection part 510 may have any structures enabling a pinning voltage to increase as the photogate 520 becomes closer. The three n-layers 630, 640 and 650 are formed as shown in FIG. 6, however, for example, two n-layers or at least four n-layers may also be formed.

The demodulation part of the pixel 500 may include the photogate 520. Here, an upper side of the demodulation part of the pixel 500 may be shielded and accordingly, an electron may not be generated by a received light photon in the demodulation part of the pixel 500. In the example embodiment of FIG. 6, an upper side of the photogate 520 may be shielded with a metal 610, noting that alternate shielding materials are also available. Referring to FIGS. 5 through 8, the photogate 520, the first transfer node TX1 530, and the second transfer node TX2 540 may be arranged in series on the P-sub. A direction of the e-field generated by the demodulation part may be determined based on a voltage applied to each of the photogate 520, the first transfer node TX1 530, and the second transfer node TX2 540. Electrons may accordingly be moved based on the determined direction of the e-field. Here, in an embodiment, the photogate 520 may be formed of polysilicon, and the first transfer node TX1 530, and the second transfer node TX2 540 may also be formed of polysilicon, or other materials. When the first transfer node TX1 530, and the second transfer node TX2 540 are formed of materials other than polysilicon, gaps may not be formed between the photogate 520 and the transfer nodes TX1 530 and TX2 540, in a different manner from FIG. 8. When there is no gap between the photogate 520 and the transfer nodes TX1 530 and TX2 540 as shown in FIG. 8, the electron may be more efficiently demodulated. The shielding metal 610 of FIG. 8 may have a same configuration as that of FIG. 5, in shielding the photogate 520 but not the detection part 510, though differing shielding techniques are available.

The first FD node FD1 550 and the second FD node FD2 560 may correspond to accumulation nodes in which electrons transferred by transfer nodes 530 and 540 are accumulated.

The pixel 500 shown in FIGS. 5 through 8 may move the electron to the demodulation part by applying the e-field to the detection part 510. The pixel 500 may be configured to enable a pinning voltage of the pinned photodiode to be significantly changed without a geometry of the pinned photodiode being significantly different from a normal configuration. Specifically, the pixel 500 may be designed to have differing magnitudes of pinning voltages based on differing doping densities or junction depths of each of the n-layers 630, 640, and 650. Depending on embodiments, differing doping densities and/or junction depths may be used.

Additionally, as noted, the pixel 500 may increase an electron transfer speed using the photogate 520. When a voltage applied to the photogate 520 is increased, electrons moved by a difference in pinning voltage may be gathered in the photogate 520. In other words, the photogate 520 may store the electron generated by the detection part 510 for a predetermined period of time. When a strong e-field is generated by increasing a voltage applied to the first transfer node TX1 530 or the second transfer node TX2 540 while reducing the voltage applied to the photogate 520, after the electrons are gathered in the photogate 520, the electrons may be quickly transferred to the first FD node FD1 550 or the second FD node FD2 560.

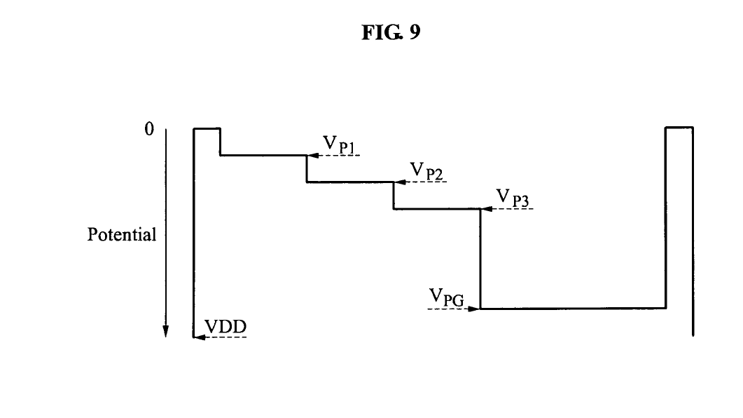

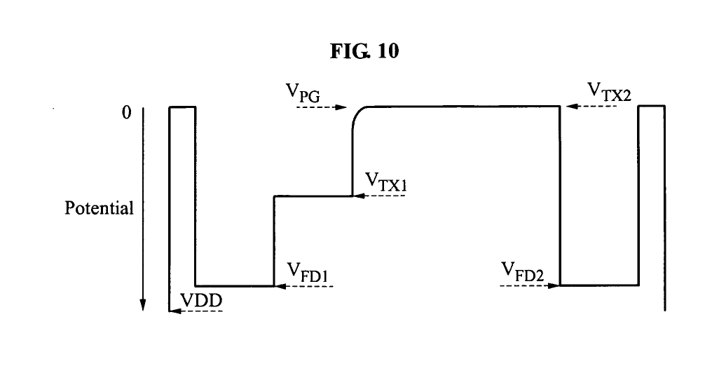

FIG. 9 illustrates an electric potential formed on the detection part 510 and the photogate 520 of FIG. 5, according to one or more embodiments. FIG. 10 illustrates an electric potential formed on the demodulation part of FIG. 5, according to one or more embodiments. Specifically, the electric potentials shown in FIGS. 9 and 10 may be respectively formed on the detection part 510 of FIG. 6, and the demodulation part of FIG. 8. FIGS. 9 and 10 schematically represent that electrons may be easily moved by a difference in electric potential of each area. Values of the electric potentials of FIGS. 9 and 10 are increased downward from a reference value of ‘0’.

In FIG. 9, V_{P1}, V_{P2}, and V_{P3} respectively denote an electric potential of the n-layer N1 630, an electric potential of the n-layer N2 640, and an electric potential of the n-layer N3 650. Additionally, V_{PS} denotes an electric potential of the photogate 520, and may be adjusted based on the voltage applied to the photogate 520.

In FIG. 10, V_{TX1} denotes an electric potential of the first transfer node TX1 530, and may be adjusted based the voltage applied to the first transfer node TX1 530. V_{PS} and V_{TX2} respectively denote an electric potential of the photogate 520, and an electric potential of the second transfer node TX2 540, and may be respectively adjusted based on the voltage applied to the photogate 520 and the voltage applied to the second transfer node TX2 540. Additionally, V_{FD1} and V_{FD2} respectively denote an electric potential of the first FD node FD1 550, and an electric potential of the second FD node FD2 560.

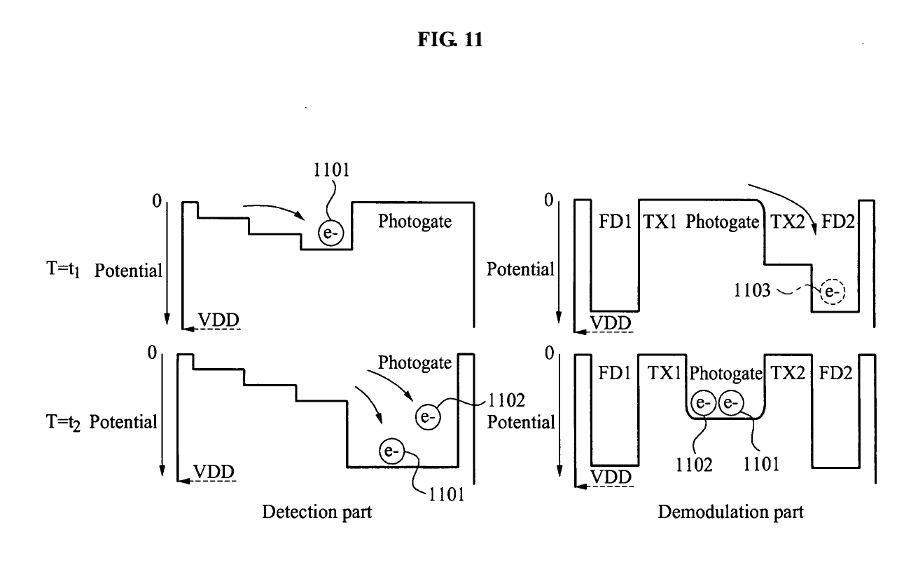

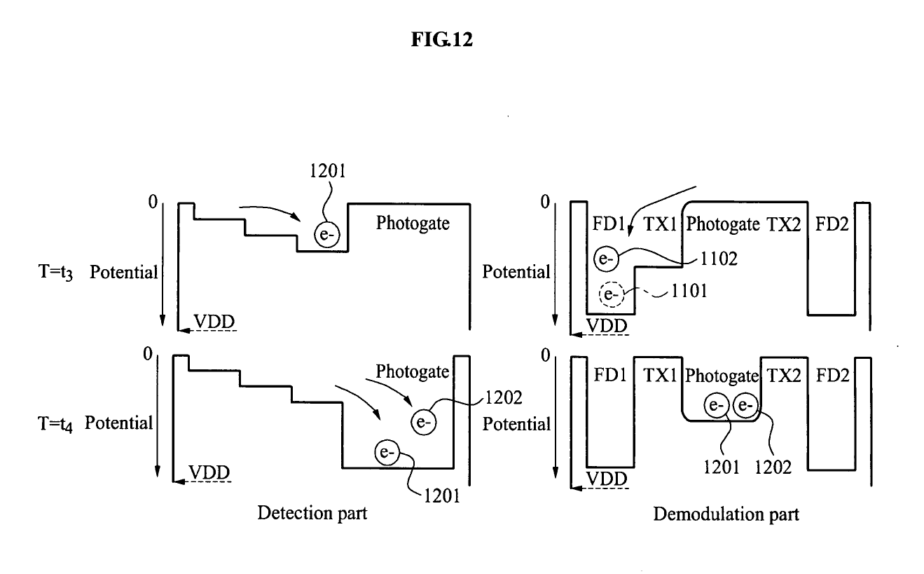

FIGS. 11 and 12 illustrate examples of a method of operating an image sensor, according to one or more embodiments. Hereinafter, the method of operating the pixel of the image sensor will be described with reference to FIGS. 5 through 8, 11, and 12, noting that embodiments are not limited to the same. In one or more embodiments, the method may be implemented through four time periods t₁, t₂, t₃, and t₄.

Referring to FIG. 11, in the first time period t₁, an electron 1101 generated by the detection part 510 may be transferred to the front side of the demodulation part. Specifically, when the electric potential of the photogate 520 is reduced, the electron 1101 may be gathered in front of the photogate 520, in the first time period t₁. Here, the potential of the photogate 520 is lower than the potential of the detection part 510, so the electron is moved only up to the front of the photogate 520, by the corresponding e-field generated by the detection part 510.

Additionally, in the first time period t₁, an electron 1103 stored in the demodulation part, e.g., as shown in FIG. 8, in a previous time period, e.g., tₒ, may be demodulated through the second transfer node TX2 540. Specifically, when the electric potential of the second transfer node TX2 540 is increased, while the potential of the photogate 520 is lower than TX2 540, and potentially FD2 560, the electron 1103 may be demodulated through at least the second transfer node TX2 540, in the first time period t₁. Electron 1103 is shown in FIG. 11 with dashes to represent the potential continued presence of the electron 1103, e.g., from time period t₀, during this illustrated time period t₁ of FIG. 11. Likewise, electron 1101 is shown in FIG. 12 with dashes to represent the potential continued presence of this electron 1101, e.g., from time period t₂, during the illustrated time period t₃ of FIG. 12.

In the first time period t₁, the electric potential of the photogate 520 may be equal to the electric potential of the first transfer node TX1 530, and may be lower than the electric potential of the detection part 510 and the electric potential of the second transfer node TX2 540. Accordingly, the electron 1101 generated by the detection part 510 may be transferred to the front side of the photogate 520 by the e-field, and the electron 1103 stored in the photogate may be accumulated in the second FD node FD2 560 through the second transfer node TX2 540.

In a second time period t₂, a voltage may be applied to the demodulation part so that the electron 1101, having been moved to the front side of the demodulation part in t₁, may be stored in the demodulation part. Specifically, in the second time period t₂, when the electric potential of the photogate 520 is increased, and when the electric potential of the first transfer node TX1 530 and the electric potential of the second transfer node TX2 540 are reduced, the electron 1101 may be moved to the photogate 520 by a strong e-field. Here, the electric potential of the photogate 520 may be higher than the electric potential of the first transfer node TX1 530 and the electric potential of the second transfer node TX2 540. Accordingly, the electron 1101 may remain unchanged in the photogate 520. Additionally, a new electron 1102 may be generated by a reflected light in the detection part even in the second time period t₂, and the generated electron 1102 may also be moved to the photogate 520.

Referring to FIG. 12, in a third time period t₀, when the electric potential of the photogate 520 is reduced, an electron 1201 generated in the third time period t₃ may be moved to the front side of the photogate 520.

In the third time period t₃, when the electric potential of the first transfer node TX1 530 is increased, the electrons 1101 and 1102 stored in the photogate 520 in the second time period t₂ may be accumulated in the first FD node FD1 550 through the first transfer node TX1 530. In other words, in the third time period t₃, the electric potential of the photogate 520 may be equal to the electric potential of the second transfer node TX2 540, and may be lower than the electric potential of the detection part 510 and the electric potential of the first transfer node TX1 530.

In a fourth time period t₄, the detection part 510 and demodulation part may have the same electric potentials in the second time period t₂. Accordingly, an electron 1201 moved to the front side of the photogate 520 in the third time period t₃ may be gathered in the photogate 520 in the fourth time period t₄. Additionally, an electron 1202 may be generated by a reflected light in the detection part even in the fourth time period t₄, and the generated electron 1202 may also be moved to the photogate 520.

The electric potentials of the photogate 520, the first transfer node TX1 530, and the second transfer node TX2 540 may be determined based on the electric potential of the detection part 510 in each of the time periods, and there is no limitation thereto. For example, the electric potential of the photogate 520 may be reduced to values other than ‘0’, as shown in FIGS. 11 and 12.

Here, considering the time period t₀ before the first time period t₁, when electron 1103 was generated and moved to the photogate 520, in four time periods t₀-t₀, electron 1103 has been generated and accumulated in FD2 560 through the second transfer node TX2 540, and electrons 1101 and 1102 have been generated and accumulated in FD1 550 through the first transfer node TX1 530.

Electrons may be generated while a reflected light is received by the pixel of the image sensor. Specifically, electrons may be generated in the detection part 510 in a time period that overlaps a time period during which the reflected light is received, among the time periods t₁, t₂, t₃, and t₄ of FIGS. 11 and 12, for example. While electrons may be generated in the detection part 510 by the reflected light for each of the time periods t₁, t₂, t₃, and t₄ as described above with reference to FIGS. 11 and 12, this is merely an example. Whether the time period during which the reflection light is received overlaps each of the time periods t₁, t₂, t₃, and t₄, may be determined based on a period for radiating a light (for example, an IR) to a target object, a voltage applying timing for the photogate 520, the first transfer node TX1 530, and the second transfer node TX2 540, a distance between the target object and the image sensor, and the like.

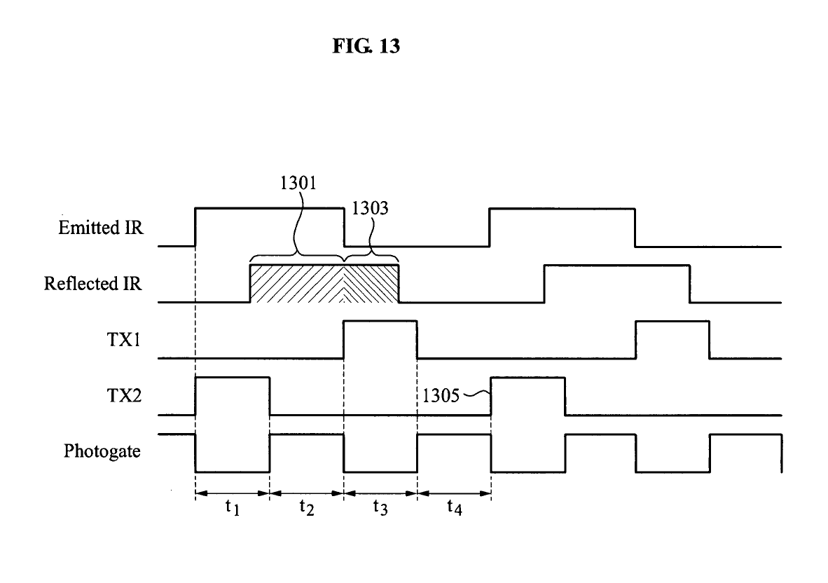

FIG. 13 illustrates a timing diagram of operations of the pixel shown in FIGS. 11 and 12. All of the time periods t₁, t₂, t₃, and t₄ overlap the time period during which the reflected light is received, as described above with reference to FIGS. 11 and 12. However, in FIG. 13, a portion of the first time period t₁, a portion of the third time period t₃, and the second time period t₂ overlap the time period during which the reflected light is received.

In FIG. 13, IR may be assumed as the emitted light. Other detectable lights may also be used as emitted lights. Additionally, a sine wave, a triangle wave, and a pulse wave may be used in a demodulation scheme, however, FIG. 13 illustrates the simplest square wave. In other words, the emitted light or the demodulation scheme may not be limited to those of FIG. 13.

Referring to FIG. 13, electrons are generated in time periods 1301 and 1303 during which a reflected IR is received by a pixel of an image sensor. Here, the electron generated in the time period 1301 may be transferred to the first FD node FD1 550 through the first transfer node TX1 530 in the third time period t₃. Additionally, the electron generated in the time period 1303 may be transferred to the second FD node FD2 560 in a time period 1305 where the TX2 is high after the fourth time period t₄, e.g., in a time period t₅. In other words, an area indicated by dashed lines in FIG. 13 may be proportional to an amount of electrons accumulated in the first FD node FD1 550 or the second FD node FD2 560, respectively. Accordingly, a depth may be measured based on the area indicated by the dashed line in the reflected IR. The time periods t1, t2, t3, and t4 may be changed by adjusting voltages applied to the photogate 520 and the transfer nodes TX1 530 and TX2 540. As noted above, the images sensor 400 may include configurations, such as additional circuit configurations, performing such a TOF analysis and generate a determined depth for one or more respective pixels.

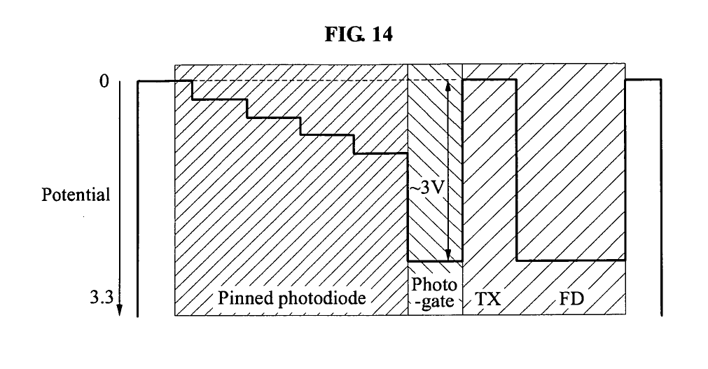

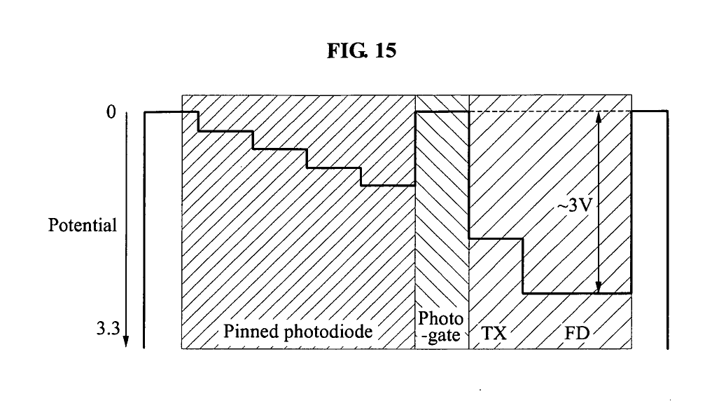

FIGS. 14 and 15 illustrate an electric potential of a pixel of an image sensor, according to one or more embodiments. Referring to FIGS. 14 and 15, the pixel of the image sensor may be divided into a detection part, such as shown in FIG. 6, and a demodulation part, such as shown in FIG. 8, and voltages may be applied to each of the detection part and the demodulation part, so that a high e-field may be generated even at a low voltage. For example, first, an e-field of about 3V is formed in the detection part (FIG. 14), and then a PG voltage is reduced in the demodulation part, thereby again forming an e-field of about 3V in the demodulation part (FIG. 15). Accordingly, a high e-field may still be obtained when a pinned photodiode is being used and thus, it is possible to increase a demodulation speed.

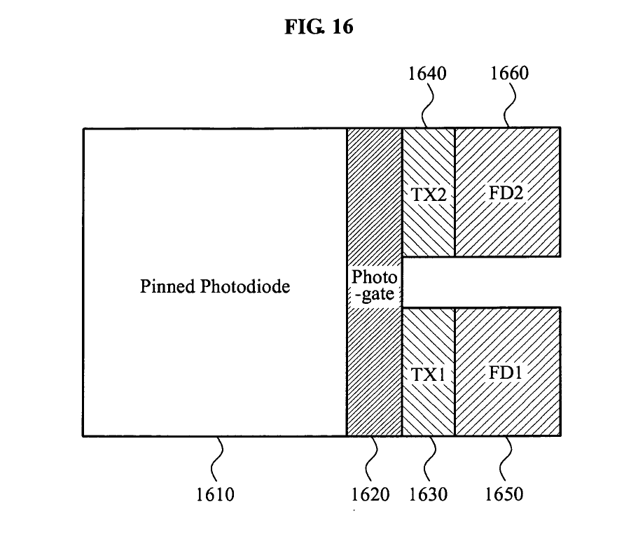

FIGS. 16 through 19 illustrate various modifications of a pixel of an image sensor, according to one or more embodiments. In FIGS. 16 through 19, a pinned photodiode may be used as a detection part of the pixel.

A pixel of FIG. 16 may be formed by modifying sizes and locations of the first transfer node TX1 530, the second transfer node TX2 540, the first FD node FD1 550, and the second FD node FD2 560 of the pixel 500 of FIG. 5, for example. In FIG. 5, the photogate 520 may be formed on one side of the detection part 510, and the first transfer node TX1 530 and the second transfer node TX2 540 may be respectively formed between the photogate 520 and the first FD node FD1 550, and between the photogate 520 and the second FD node FD2 560. Additionally, the first transfer node TX1 530 may face a side of the photogate 520, and the second transfer node TX2 540 may face an opposite side of the photogate 520.

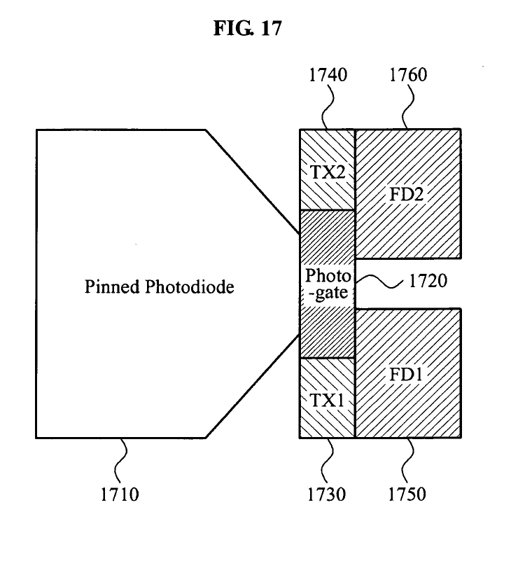

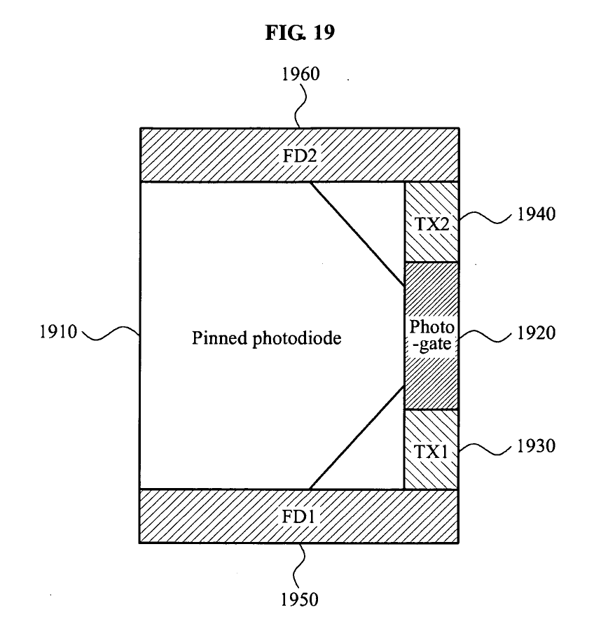

Referring to FIG. 16, transfer nodes TX1 1630 and TX2 1640 may be arranged in series with a photogate 1620. Specifically, the transfer nodes TX1 1630 and TX2 1640 may be formed on a surface facing a surface where a detection part, for example the pinned photodiode 1610, is formed, and the photogate 1620 may be intervened between the pinned photodiode and the transfer nodes TX1 1630 and TX2 1640. Referring to FIGS. 17 and 19, transfer nodes TX1 1730, 1930 and TX2 1740, 1940 are arranged at both ends or lateral sides of the photogate 1720, 1920. When the transfer nodes TX1 1630 and TX2 1640 are arranged in series with the photogate 1620 as shown in FIG. 16, a contact area between the photogate 1620 and the transfer nodes TX1 1630 and TX2 1640 may be increased. As the contact area between the photogate 1620 and the transfer nodes TX1 1630 and TX2 1640 increases, electrons may be more efficiently transferred. Here, a speed for transferring electrons to FD nodes FD1 1650 and FD2 1660 may be adjusted based on sizes of the transfer nodes TX1 1630 and TX2 1640, for example.

In FIG. 16, FD nodes FD1 1650 and FD2 1660 are arranged in series with the photogate 1620, and the transfer nodes TX1 1630 and TX2 1640. When the FD nodes FD1 1650 and FD2 1660 are arranged in series with the transfer nodes TX1 1630 and TX2 1640 as shown in FIG. 16, contact areas between the transfer nodes TX1 1630 and TX2 1640, and the FD nodes FD1 1650 and FD2 1660 may be increased. In FIG. 19, FD nodes FD1 1950 and FD2 1960 are respectively arranged at ends or lateral sides of transfer nodes TX1 1930 and TX2 1940.

A pixel of FIG. 17 may be formed by modifying a shape or geometry of the detection part 510 (for example, a pinned photodiode), and by modifying sizes and locations of the first FD node FD1 550 and the second FD node FD2 560 of the pixel 500 of FIG. 5. The geometry or shape of the pinned photodiode 1610 in FIG. 16 will be considered normal, herein, while FIGS. 17-19 have pinned photodiodes 1710, 1810, and 1910 having differing geometries or shapes. Here, even though the geometry may be different, aspects of the differing pinning voltages described in relation to FIG. 6, would still be employed in FIGS. 16-19, in one or more embodiments.

Referring to FIG. 17, a width of the pinned photodiode 1710 may be reduced as a photogate 1720 becomes closer. When the width of the pinned photodiode 1710 is reduced as the photogate 1720 becomes closer, a size of the photogate 1720 may be reduced, so that it is possible to reduce power consumption when the pixel is operated. In FIG. 17, FD nodes FD1 1750 and FD2 1760 are arranged in series with the photogate 1720.

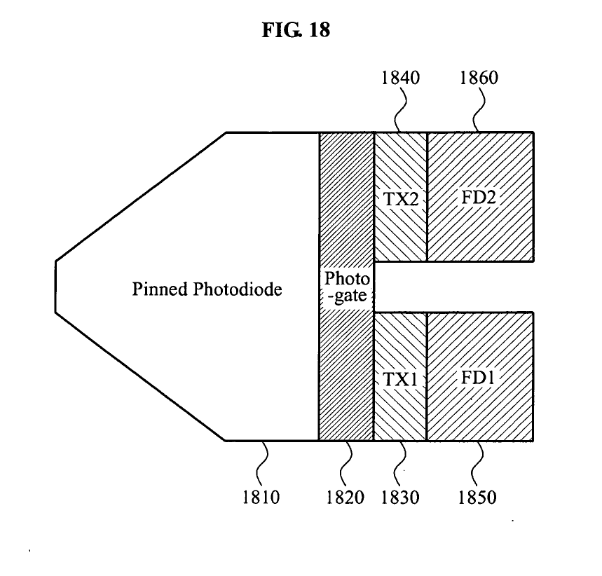

A pixel of FIG. 18 may be formed by modifying a shape of the detection part (for example, the pinned photodiode 1610) of the pixel of FIG. 16, for example. Specifically, a width of the pinned photodiode 1810 of FIG. 18 may be increased as a photogate 1820 becomes closer. In this example, an n-layer of the pinned photodiode 1810 may be horizontally increased, so that a pinning voltage may be increased as the photogate 1820 becomes closer, thereby increasing a transfer speed. In an embodiment, in FIG. 18, transfer nodes TX1 1830 and TX2 1840, and FD nodes FD1 1850 and FD2 1860 may have same or similar structures as those of FIG. 16.

A pixel of FIG. 19 may be formed by modifying a shape of the detection part 510 (for example, a pinned photodiode) of the pixel 500 of FIG. 5, for example. In an embodiment, the pinned photodiode 1910 of FIG. 19 may have a same or similar structure as the pinned photodiode 1710 of FIG. 17. In an embodiment, in FIG. 19, transfer nodes TX1 1930 and TX2 1940 may have same or similar structures as those of FIG. 17, and FD nodes FD1 1950 and FD2 1960 may be arranged with greater surface area along ends or lateral sides of the transfer nodes TX1 1930 and TX2 1940.

As shown in FIGS. 16 through 19, locations of the photogate, the transfer nodes, and the FD nodes may be changed, and a shape of the detection part may also be variously changed. Accordingly, it is possible to modify locations and shapes of a photogate, transfer nodes, and FD nodes, based on various specifications of an image sensor and/or pixels of the image sensor, for example, for a desired demodulation speed, quantum efficiency, fill factor, and the like.

In one or more embodiments, the image sensor 400 of FIG. 4 is representative of a single pixel, representative of one or more pixels with a correlated double sampling portion, representative of each of plural pixels within the image sensor, or representative of a depth measuring device having a depth measuring unit to interpret information provided by the image sensor or single pixel. In one or more embodiments, the single pixel and image sensor are also configured to detect light for a mono or color image, in a normal manner. Likewise, the image sensor 400 may be representative of a camera monitoring system, a motion recognition system, a robot vision system, a vehicle with distance recognition, or a camera system separating observed foreground and backgrounds based on depth information. For example, the TOF analysis discussed above with regard to FIG. 4, may be calculated by the image sensor or output and analyzed by a processor, such as in a camera device. One or more embodiments include such a camera device having such a processor and the image sensor, and methods for operation of the same. The described image sensor 400 is formed of a substrate, such as a substrate having particular N and P portions, as described above. In one or more embodiments, the image sensor 400 or pixel of the same is a CMOS image sensor (CIS).

In one or more embodiments, apparatus, system, and unit descriptions herein may include one or more hardware processing elements. For example, each described unit may include one or more processing elements performing the described operation, desirable memory, and any desired hardware input/output transmission devices.

In addition to the above described embodiments, embodiments can also be implemented through computer readable code/instructions in/on a non-transitory medium, e.g., a computer readable medium, to control at least one processing device, such as a processor or computer, to implement any above described embodiment. The medium can correspond to any defined, measurable, and tangible structure permitting the storing and/or transmission of the computer readable code.

The media may also include, e.g., in combination with the computer readable code, data files, data structures, and the like. One or more embodiments of computer-readable media include magnetic media such as hard disks, floppy disks, and magnetic tape; optical media such as CD ROM disks and DVDs; magneto-optical media such as optical disks; and hardware devices that are specially configured to store and perform program instructions, such as read-only memory (ROM), random access memory (RAM), flash memory, and the like. Computer readable code may include both machine code, such as produced by a compiler, and files containing higher level code that may be executed by the computer using an interpreter, for example. The media may also be a distributed network, so that the computer readable code is stored and executed in a distributed fashion. Still further, as only an example, the processing element could include a processor or a computer processor, and processing elements may be distributed and/or included in a single device.

The computer-readable media may also be embodied in at least one application specific integrated circuit (ASIC) or Field Programmable Gate Array (FPGA), which executes (processes like a processor) program instructions.

While aspects of the present invention has been particularly shown and described with reference to differing embodiments thereof, it should be understood that these embodiments should be considered in a descriptive sense only and not for purposes of limitation. Descriptions of features or aspects within each embodiment should typically be considered as available for other similar features or aspects in the remaining embodiments. Suitable results may equally be achieved if the described techniques are performed in a different order and/or if components in a described system, architecture, device, or circuit are combined in a different manner and/or replaced or supplemented by other components or their equivalents.

Thus, although a few embodiments have been shown and described, with additional embodiments being equally available, it would be appreciated by those skilled in the art that changes may be made in these embodiments without departing from the principles and spirit of the invention, the scope of which is defined in the claims and their equivalents.

What is claimed is:

1. An image sensor, with at least one pixel of the image sensor comprising:
a detection portion to transfer an electron, generated by the detection portion after receiving light, with the detection portion comprising a plurality of doping areas having different pinning voltages to apply an e-field in the detection portion to transfer the electron toward a demodulation portion of the pixel; and
the demodulation portion to transfer the electron toward at least one node to accumulate one or more electrons.

2. The image sensor of claim 1, wherein the pixel is configured to apply another e-field that causes the electron to be transferred by the demodulation portion toward the at least one node to accumulate one or more electrons.

3. The image sensor of claim 1, wherein the plurality of doping areas respectively comprise a plurality of n-layers, and
wherein, as each of the plurality of n-layers is configured to be increasingly closer to the demodulation part, a respective pinning voltage of each of the plurality of n-layers becomes higher.

4. The image sensor of claim 3, wherein the respective pinning voltage of each of the plurality of n-layers is based further on a respective doping density.

5. The image sensor of claim 1, wherein the plurality of doping areas respectively comprise a plurality of n-layers, and wherein a respective pinning voltage of each of the plurality of n-layers is based on a respective doping density or junction depth.

6. The image sensor of claim 1, wherein the plurality of doping areas respectively comprise a plurality of p-layers, and
wherein, as each of the plurality of p-layers is configured to be increasingly closer to the demodulation portion, a respective pinning voltage of each of the plurality of p-layers becomes higher.

7. The image sensor of claim 6, wherein the respective pinning voltage of each of the plurality of p-layers is further based on a respective doping density.

8. The image sensor of claim 1, wherein the plurality of doping areas respectively comprise a plurality of p-layers, and wherein a respective pinning voltage of each of the plurality of p-layers is based on a respective doping density or junction depth.

9. The image sensor of claim 1, wherein the detection portion is configured with a pinned photodiode comprising the plurality of doping areas.

10. The image sensor of claim 1, further comprising a photogate to receive the electron transferred by the detection portion toward the demodulation portion.

11. The image sensor of claim 10, wherein the photogate is included in the demodulation portion.

12. The image sensor of claim 10, wherein the photogate is shielded from receipt of the light.

13. The image sensor of claim 10, wherein the pixel is configured such that a changing of electric potential of the photogate controls an application of another e-field of the demodulation portion that causes the received electron to be transferred from the photogate toward the at least one node to accumulate one or more electrons.

14. The image sensor of claim 10, wherein, the pixel is configured such that:
an electric potential of the photogate is lower than an electric potential of the detection portion and an electric potential of a first transfer node in a first time period; and
the electric potential of the photogate is higher than the electric potential of the detection portion and the electric potential of the first transfer node in a second time period, immediately after the first time period.

15. The image sensor of claim 14, wherein, the pixel is further configured such that an electric potential of the photogate is lower than an electric potential of the detection portion and an electric potential of a second transfer node in a third time period, immediately after the second time period, such that the electric potential of the photogate and the first transfer node in the third time period do not cause an electron stored by the photogate to be transferred to the first transfer node and such that the electric potential of the photogate and the second transfer node in the third time period cause the electron stored by the photogate to be transferred to the second transfer node.

16. The image sensor of claim 14, wherein, the pixel is further configured such that the electric potential of the photogate and the electric potential of the detection portion in the second time period causes the electron to be transferred from the detection portion to the photogate, while the electric potential of the photogate and the electric potential of the first transfer node causes the electron to not be transferred to the first transfer node.

17. The image sensor of claim 14, wherein, the pixel is further configured such that the electric potential of the photogate and the electric potential of the detection portion in the first time period causes the electron to be transferred within the detection portion toward an edge of the detection portion close to the photogate and to not be stored by the photogate, and the electric potential of the photogate and the electric potential of the first transfer node in the first time period causes an electron stored by the photogate to be transferred to the first transfer node.

18. The image sensor of claim 14, wherein, the pixel is further configured such that when the electric potential of the photogate is greater than the first transfer node and a second transfer node in the second time period, with the second transfer node being configured to be transferred an electron from the photogate, the photogate stores a received electron and does not transfer the stored electron to either of the first transfer node and the second transfer node in the second time period.

19. The image sensor of claim 14, wherein, the pixel is further configured such that an electron stored in the photogate before the first time period is moved to the first transfer node in the first time period, and the electron transferred by the detection portion toward the demodulation portion is moved to the photogate in the second time period.

20. An image sensor, with at least one pixel comprising:
a demodulation portion to demodulate a stored electron through at least one transfer node, the stored electron being stored by the demodulation portion prior to a first time period; and
a detection portion to transfer a generated electron to a front side of the demodulation portion in the first time period, the generated electron being generated by the detection portion upon receiving light in the first time period,
wherein the pixel is configured to move the transferred electron to the demodulation portion in a second time period.

21. The image sensor of claim 20, the pixel being configured such that a potential of the detection portion applies a drift force to transfer the generated electron to at least the front side of the demodulation unit in the first time period, at least a potential of the detection portion in the second time period applies a drift force for the moving of the transferred electron to a storage of the demodulation portion, and at least one potential of the demodulation portion in the second time period prevents application of a drift force to transfer the stored electron to the at least one transfer node within the demodulation portion during the second time period.

22. The image sensor of claim 20, wherein the pixel is configured to move the stored electron to the at least one transfer node during the first time period.

23. The image sensor of claim 20, wherein the detection portion comprises a plurality of doping areas, and a pinning voltage of each of the plurality of doping areas is based on a respective doping density or junction depth.

24. The image sensor of claim 20, wherein the detection portion is configured with a pinned photodiode comprising the plurality of doping areas.

25. The image sensor of claim 24, wherein the pinned photodiode has a narrowing geometry toward the demodulation portion.

26. The image sensor of claim 24, wherein the pinned photodiode has a widening geometry toward the demodulation potion.

26. The image sensor of claim 20, wherein the demodulation portion comprises a photogate.

27. A method of operating an image sensor that includes at least one pixel including a detection portion to generate an electron upon receipt of light, and a demodulation portion to demodulate the generated electron including a first transfer node and a second transfer node, the method comprising:
controlling an electric potential of the detection portion to transfer the generated electron toward the demodulation portion;
controlling an electric potential within the pixel to cause the generated electron to be stored for a predetermined time period; and
controlling an electric potential of the demodulation portion to cause the stored electron to be transferred after the predetermined time period to the first transfer node.

28. The method of claim 27, further comprising:
controlling an electric potential within the pixel to cause another generated electron to be stored for the predetermined time period; and
controlling at least one electric potential of the demodulation portion to cause the other stored electron to be transferred after the predetermined time period to the second transfer node, and to cause the other stored electron to not be transferred after the predetermined time period to the first transfer node.

29. The method of claim 28, further comprising:
accumulating first electrons transferred to the first transfer node and accumulating second electrons transferred to the second transfer node;
comparing the accumulated first electrons to the accumulated second electrons and determining a time of flight for the light.

30. At least one non-transitory medium comprising computer readable code to control at least one processing device to implement the method of claim 28.

31. A method of operating an image sensor that includes at least one pixel including a detection portion to generate an electron upon receipt of light, and a demodulation portion to demodulate the generated electron, the demodulation portion including a photogate, a first transfer node, and a second transfer node, the method comprising:
storing the electron generated by the detection portion in the photogate in a first time period; and
demodulating the electron stored in the photogate, through one of the first transfer node and the second transfer node, in a second time period, immediately after the first time period.

32. The method of claim 31, wherein the storing, in the first period, comprises setting an electric potential of the photogate and electric potentials of both of the first transfer node and the second transfer node, such that the electric potential of the photogate is higher than the electric potentials of both the first transfer node and the second transfer node.

33. The method of claim 31, wherein the demodulating, in the second period, comprises setting an electric potential of the photogate and an electric potential of one of the first transfer node and the second transfer node, such that the electric potential of the one of the first transfer node and the second transfer node is higher than an electric potential of the photogate.

34. The method of claim 31, further comprising controlling an electric potential of the photogate to be lower than an electric potential of the detection portion and an electric potential of the second transfer node, while controlling the electric potential of the first transfer node such that the electric potential of the photogate and the first transfer node do not cause the stored electron to be transferred to the first transfer node and controlling the electric potential of the photogate and the second transfer node to cause the stored electron stored to be transferred to the second transfer node.

35. The method of claim 31, further comprising controlling an electric potential of the photogate and an electric potential of the detection portion to cause the electron generated by the detection portion to be transferred from the detection portion to the photogate, while controlling electric potentials of the first transfer node and the second transfer node to cause the stored electron to not be transferred to either of the first transfer node and the second transfer node.

36. The method of claim 31, further comprising controlling an electric potential of the photogate and an electric potential of the detection portion to cause the electron generated by the detection portion to be transferred within the detection portion toward an edge of the detection portion close to the photogate and to not be moved to the photogate, while controlling the electric potential of the photogate and the electric potential of the first transfer node to cause the stored electron to be transferred to the first transfer node.

37. The method of claim 31, further comprising controlling an electric potential of the photogate to be greater than electrical potentials of both the first transfer node and the second transfer node, to prevent transfer of the stored electron of the photogate to either of the first transfer node and the second transfer node.

38. At least one non-transitory medium comprising computer readable code to control at least one processing device to implement the method of claim 31.
